(19) United States
(12) Patent Application Publication
(10) Pub. No.: US 2021/0195813 A1
(43) Pub. Date: Jun. 24, 2021

(54) ELECTROMAGNETIC INTERFACE SHIELD

(71) Applicant: BAE Systems plc, London (GB)

(72) Inventors: Christopher Richard Lucas, Christchurch, Bournemouth (GB); Carl Martin Matthews, Christchurch, Bournemouth (GB)

(73) Assignee: BAE Systems plc, London (GB)

(21) Appl. No.: 16/754,858

(22) PCT Filed: Nov. 6, 2018
(86) PCT No.: PCT/GB2018/053217

§ 371 Date: Apr. 9, 2020

(30) Foreign Application Priority Data
Nov. 17, 2017 (GB) 1719046.3

(51) Int. Cl. H05K 9/00

(52) U.S. Cl. CPC H05K 9/0018; H05K 9/0049

(57) ABSTRACT

The present invention relates to an enclosure and method of manufacture of an enclosure arranged to define a cavity for electromagnetic shielding of equipment to be housed within the cavity, the enclosure comprising: an aperture (16) arranged to allow access to the enclosure; a conductive membrane (18) arranged to close the aperture; and a waveguide element (20) arranged between the conductive membrane (18) and the cavity; wherein the waveguide element (20) and conductive membrane (18) are configured to attenuate electromagnetic radiation originating from the equipment to be housed within the enclosure (10) thereby to inhibit the transmission of electromagnetic radiation from the enclosure via the aperture (16).

The present invention relates to an enclosure for electromagnetic shielding of equipment and more particularly to an enclosure which contains an aperture.

When designing enclosures for devices it is important that the components are protected from electromagnetic radiation which may harm or influence the way the devices operate. This is typically achieved by isolating the device from external electromagnetic radiation by shielding. Shielding often includes a conductive enclosure used to attenuate electromagnetic radiation and is often referred to as a Faraday cage. The level of attenuation depends on a number of factors including the material used, material thickness, and the size of any apertures in the shielding. It is also desirable to shield equipment in order that electromagnetic radiation generated by the equipment cannot be measured by external devices as this may allow sensitive information related to the equipment to be accessed.

A purpose of the invention is to mitigate the risk of electromagnetic radiation generated by equipment exiting an enclosure via an aperture.

According to a first aspect of the invention there is an enclosure arranged to define a cavity for electromagnetic shielding of equipment to be housed within the cavity, the enclosure comprising: an aperture arranged to allow access to the enclosure; a conductive membrane arranged to close the aperture; and a waveguide element arranged between the conductive membrane and the cavity; wherein the waveguide element and conductive membrane are configured to attenuate electromagnetic radiation originating from the equipment to be housed within the enclosure thereby to inhibit the transmission of electromagnetic radiation from the enclosure via the aperture. In this manner the arrangement may allow an aperture to be present in the enclosure whilst not compromising the electromagnetic shielding provided by the enclosure. The waveguide element and enclosure may be substantially or in part a conductive or dielectric material.

The enclosure may further comprise a faceplate and a cooperating back-box arranged to define the cavity. In this manner the arrangement may allow greater access to the equipment within the cavity when the equipment is not in use.

The aperture may be aligned with a reset switch for equipment to be housed within the cavity thus allowing change of state of the electronic equipment without having to dismantle the enclosure. This may be desirable if the reset switch is infrequently used and requires some level of protection from accidental operation. The arrangement may serve the purpose that the state of the electronic equipment can be changed rapidly in the case of an emergency.

The aperture may be of sufficient diameter to ensure the reset switch is accessible by a user's digit. The size of the aperture will be dependent on its function.

The conductive membrane may be formed from foil. In use the foil may be pierced by the inserting of a digit or other device that may be used to actuate the reset switch. The pierced foil provides the added benefit that it indicates whether the reset switch has been actuated, and may warn a user that the electromagnetic shielding has been compromised.

The conductive membrane may comprise a mesh structure. The structure and configuration of the waveguide element may mean that the conductive membrane may not need to be pierced in order for the reset switch to be actuated. A deformable mesh may still allow a digit to actuate the reset switch directly, or a deformable mesh could move the waveguide element to allow the switch to be actuated. In another embodiment the mesh may be pierced and may provide an indication that the reset switch has been actuated.

The conductive membrane may be a frangible material. The frangible material may indicate whether the reset switch has been actuated, and may warn a user that the electromagnetic shielding has been compromised.

The length of the waveguide element may be substantially twice that of the wavelength of the predicted maximum frequency output from the equipment to be housed within the cavity. It will be understood that the calculations to determine the length of the waveguide element to attenuate electromagnetic radiation originating within the cavity thereby inhibiting the transmission of electromagnetic radiation from the enclosure via the aperture are known to the person skilled in the art.

The waveguide element may be tubular, and if configured to align with the aperture and conductive membrane will allow access to the cavity defined by the enclosure.

One end of the waveguide element may be arranged to abut against the internal surface of the conductive membrane, aiding effective attenuation of electromagnetic radiation from the equipment housed within the enclosure ensuring that the conductive membrane can effectively inhibit electromagnetic radiation from exiting the enclosure.

The waveguide element may be fixed to the interior of the enclosure and arranged such that the central axis of the waveguide element and the centre of the aperture are substantially aligned along a common access, preferably co-axially aligned, ensuring effective inhibiting of electromagnetic radiation from the equipment housed within the enclosure. This alignment has the further benefit of allowing access to the reset switch through the aperture.

The waveguide element may be fixed to the interior of the enclosure by adhesive, providing a secure bond between the waveguide element and the enclosure. The adhesive is preferably an electrically conductive adhesive.

The waveguide element may be releasably connected to the interior of the enclosure and arranged such that the central axis of the waveguide element and the centre of the aperture are substantially aligned along a common axis. This connection enables replacement of the waveguide element depending on the amount of electromagnetic attenuation required. This connection has the further benefit of enabling the conductive membrane to be replaced once it has been pierced.

The waveguide element may be releasably connected to the interior of the enclosure by a threaded connection enabling the waveguide element to be removed and replaced as required.

The waveguide element may be releasably connected to the interior of the enclosure by a bayonet connection enabling the waveguide element to be removed and replaced as required.

The waveguide element may be releasably connected to the interior of the enclosure by a sprung bush enabling the waveguide element to be removed and replaced as required.

According to a second aspect of the invention there is provided a method of manufacturing an enclosure arranged to define a cavity for electromagnetic shielding of equipment to be housed within the cavity, comprising the steps of: forming an aperture in the enclosure, arranged to allow access to the enclosure; providing a conductive membrane arranged to close the aperture; and providing a waveguide element arranged between the conductive membrane and the cavity; wherein the waveguide element and conductive membrane are configured to attenuate electromagnetic radiation originating from the equipment to be housed within the enclosure thereby inhibiting the transmission of electromagnetic radiation from the enclosure via the aperture.

The configuration of the waveguide and the conductive membrane enables the waveguide to attenuate the electromagnetic radiation such that when said radiation encounters the conductive membrane said radiation is at a sufficiently reduced intensity that it is inhibited from transmission from the enclosure via the aperture. This may be achieved by abutting or fixing a waveguide element to the interior of the enclosure arranged such that the central axis of the waveguide element and the centre of the aperture are substantially aligned along a common access, preferably co-axially aligned, ensuring effective inhibiting of electromagnetic radiation from the equipment housed within the enclosure. This alignment has the further benefit of allowing access to the equipment through the aperture. The tubular waveguide element and enclosure may be manufactured substantially or in part from a conductive or dielectric material.

An embodiment of the invention will now be described by way of example only and with reference to the accompanying drawings in which:—

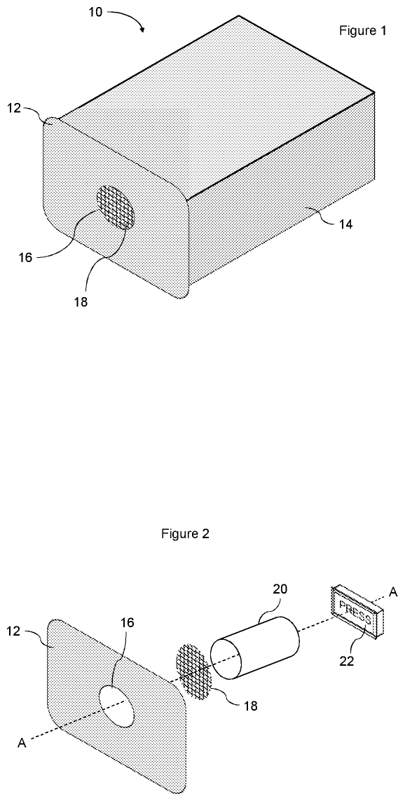

FIG. 1 shows a three dimensional view of an enclosure for electromagnetic shielding of equipment according to the present invention.

FIG. 2 shows a partially exploded three dimensional view of the component parts present inside the cavity defined by the enclosure according to the present invention.

FIG. 3 shows a three dimensional view of the conductive membrane and waveguide element in situ according to the present invention.

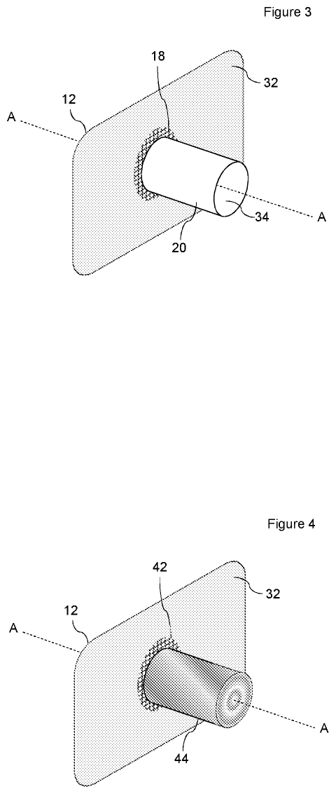

FIG. 4 shows a three dimensional view of the conductive membrane and waveguide element in situ according to an alternative embodiment of the present invention.

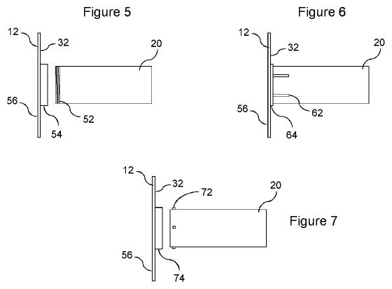

FIGS. 5 to 7 show plan views of releasable waveguide elements according to alternative embodiments of the present invention.

Referring to FIG. 1, there is provided a three dimensional view of an electrically conductive enclosure 10 comprising a multiple sided hollow back-box 14 which is open at one end (not shown). The open end is substantially closed by a faceplate 12 which when abutted against the open end of the back-box 14 defines a cavity (not shown) for electromagnetic shielding of equipment housed within the cavity. FIG. 1 also shows an aperture 16 in the faceplate 12 of the enclosure 10 to enable access to a reset switch (not shown) which enables a function of the equipment within the cavity. In order to protect the reset switch from accidental use and to indicate to a user whether or not the reset switch has been actuated, the aperture 16 is shown as being closed by an electrically conductive membrane 18 indicating in this instance that the reset switch has not been actuated.

FIG. 2 shows a partially exploded three dimensional view of the elements of the invention. In FIG. 2 the back-box 14 of FIG. 1 has been removed to aid the description. FIG. 2 shows the aperture 16 in the faceplate 12 of the enclosure 10 and the conductive membrane 18 which closes the aperture 16. FIG. 2 also shows a waveguide element 20, the proximal end of which is aligned with the conductive membrane 18 and the aperture 16 in the faceplate 12 of the enclosure 10 along axis A-A. In this embodiment the distal end of the waveguide element 20 is aligned with a switch 22 which will preferably activate a function of electrical or electronic equipment (not shown) housed within the cavity. In order to activate the switch 22 a user may use a digit to pierce the conductive membrane 18. In the embodiment shown the waveguide element 20 is tubular and the user's digit will allow direct access to the switch 22. After the switch 22 has been actuated by the user it will be clear that the electromagnetic shield has been compromised due to the visible break in the conductive membrane 18. It will also be clear that the functionality initiated by the actuation of the switch 22 has been initiated.

The length of the waveguide element 20 is defined by known equations that relate to the anticipated range of frequencies of the electromagnetic radiation that is emitted by the equipment housed in the cavity of the enclosure 10 of FIG. 1. The length of the waveguide element is preferably two wavelengths in length, and is made from a metal or metallised material.

FIG. 3 shows a three dimensional view of the elements of the invention that inhibits the transmission of electromagnetic radiation from the enclosure 10 of FIG. 1 via the aperture 16 in situ. The conductive membrane 18 which closes the aperture 16 of FIGS. 1 and 2 is abutted against the inner surface 32 of the faceplate 12 of the enclosure 10 of FIG. 1. FIG. 3 also shows the waveguide element 20 abutted against the conductive membrane 18 on the inner surface 32 of the faceplate 12 of the enclosure 10. The waveguide element is fixed to the inner surface 32 of the faceplate 12 by metallised adhesive. FIG. 3 shows the conductive membrane 18 as being larger in diameter than the diameter of the waveguide element 20 and the diameter of the aperture and the diameter of the aperture 16 which it closes. This is to illustrate the position of the conductive membrane 18 and waveguide element 20 in relation to each other, and whilst it is preferable that the conductive membrane 18 is larger in diameter than the aperture 16, it is only required that the conductive membrane 18 closes the aperture 16. The centre of the aperture 16 in the faceplate 12 of the enclosure 10, the centre of the conductive membrane 18 and the longitudinal axis of the waveguide element 20 are all substantially aligned along axis A-A. The waveguide element 20 shown in FIG. 3 is tubular and if the conductive membrane 18 is pierced the interior of the enclosure 10 can be accessed through the bore 34 of the waveguide element 20.

FIG. 4 shows a three dimensional view of an alternative embodiment of the elements of the invention that inhibit the transmission of electromagnetic radiation from the enclosure 10 of FIG. 1 via the aperture 16 in situ. In this embodiment the conductive membrane is a deformable mesh 42 which closes the aperture 16 of FIGS. 1 and 2 is abutted against the inner surface 32 of the faceplate 12 of the enclosure 10 of FIG. 1. FIG. 4 shows a solid waveguide element 44 fixed to the deformable mesh 42 by metallised adhesive to the inner surface 32 of the faceplate 12 of the enclosure 10. FIG. 4 shows the deformable mesh 42 as being larger in diameter than the diameter of the solid waveguide element 44 and the diameter of the aperture 16 which it closes. This is to illustrate the position of the deformable mesh 42 and solid waveguide element 44 in relation to each other, and whilst it is preferable that the deformable mesh 42 is larger in diameter than the aperture 16, it is only required that the deformable mesh 42 closes the aperture 16. The centre of the aperture 16 in the faceplate 12 of the enclosure 10, the centre of the deformable mesh 18 and the longitudinal axis of the solid waveguide element 44 are all substantially aligned along axis A-A. When the user wishes to actuate the switch 22 (not shown), the user presses a digit against the deformable mesh 42 which deforms under user applied pressure and moves the solid waveguide element 44 further inside the cavity away from the inner surface 32 of the faceplate 12 along axis A-A to actuate the switch 22 (not shown).

FIG. 5 shows a plan view of an alternative embodiment of the invention wherein the waveguide element 20 is releasably connected to the inner surface 32 of the faceplate 12. The waveguide element 20 comprises a male thread 52 which matches a female thread (not shown) on a nut 54 which is fixed to inner the surface 32 of the faceplate 12. In this alternative embodiment the conductive membrane 18 may be positioned at the male threaded end of the waveguide element 20, the female threaded end of the nut 54 or in the outer surface 56 of the faceplate 12.

FIG. 6 shows a plan view of another alternative embodiment of the invention wherein the waveguide element 20 is releasably connected to the inner surface 32 of the faceplate 12. The waveguide element 20 comprises at least one slot 62 which enables the waveguide element to be deformed. The slotted end of the waveguide element 20 comprises a flange (not shown), which is configured to rest in a recessed portion (not shown) of a housing member 64 when the waveguide element 20 is not deformed. In order to insert or release the waveguide element 20 from the housing member 64 the waveguide element 20 is pinched by applying pressure at diametrically opposite points substantially at the slotted end in order to reduce the diameter of the waveguide element 20. Once the waveguide element 20 is inserted into the housing member 64, or released from the housing member 64 as desired, the pressure on the slotted end of the waveguide element 20 is released and the waveguide element 20 returns to its original diameter. In this alternative embodiment the conductive membrane 18 may be positioned at the slotted end of the waveguide element 20, at the recessed portion (not shown) of the housing member 64 or in the outer surface 56 of the faceplate 12.

FIG. 7 shows a plan view of another alternative embodiment of the invention wherein the waveguide element 20 is releasably connected to the inner surface 32 of the faceplate 12. The waveguide element 20 comprises male bayonet members 72 which cooperate with reciprocal female bayonet mountings 74 fixed to the inner surface 32 of the faceplate 12 to retain the waveguide element 20 with respect to the faceplate 12. In this alternative embodiment the conductive membrane 18 may be positioned at the proximal end of the waveguide element 20, at the female bayonet mounting 74 or in the outer surface 56 of the faceplate 12.

What is claimed is:

1. An enclosure arranged to define a cavity for electromagnetic shielding of equipment to be housed within the cavity, the enclosure comprising:
an aperture arranged to allow access to the enclosure;
a conductive membrane arranged to close the aperture; and
a waveguide element arranged between the conductive membrane and the cavity;
wherein the waveguide element and conductive membrane are configured to attenuate electromagnetic radiation originating from the equipment to be housed within the enclosure thereby to inhibit the transmission of electromagnetic radiation from the enclosure via the aperture.

2. The enclosure according to claim 1 further comprising a faceplate and a cooperating back-box arranged to define the cavity.

3. The enclosure according to claim 1, wherein the aperture is aligned with a reset switch for the equipment to be housed within the cavity.

4. The enclosure according to claim 3 wherein the aperture is arranged to be of sufficient diameter to ensure the reset switch is accessible by a user's digit.

5. The enclosure according to claim 1, wherein the conductive membrane is formed from foil.

6. The enclosure according to claim 1, wherein the conductive membrane comprises a mesh structure.

7. The enclosure according to claim 1, wherein the conductive membrane is a frangible material.

8. The enclosure according to claim 1, wherein the length of the waveguide element is substantially twice that of the wavelength of the predicated maximum frequency output from the equipment to be housed within the cavity.

9. The enclosure according to claim 1, wherein the waveguide element is tubular.

10. The enclosure according to claim 1, wherein one end of the waveguide element is arranged to abut against the internal surface of the conductive membrane.

11. The enclosure according to claim 1, wherein the waveguide element is fixed to the interior of the enclosure and arranged such that the central axis of the waveguide element and the centre of the aperture are substantially aligned along a common axis.

12. The enclosure according to claim 10 wherein the waveguide element is fixed to the interior of the enclosure by metallised adhesive.

13. The enclosure according to claim 1, wherein the waveguide element is releasably connected to the interior of the enclosure and arranged such that the central axis of the waveguide element and the centre of the aperture are substantially aligned along a common axis.

14. The enclosure according to claim 13 wherein the waveguide element is releasably connected to the interior of the enclosure by a threaded connection, a bayonet connection, or a sprung bush.

15. (canceled)

16. The enclosure according to claim 2, wherein the aperture is aligned with a reset switch for the equipment to be housed within the cavity.

17. The enclosure according to claim 2, wherein the conductive membrane is formed from foil.

18. The enclosure according to claim 3, wherein the conductive membrane is formed from foil.

19. The enclosure according to claim 4, wherein the conductive membrane is formed from foil.

20. The enclosure according to claim 2, wherein the conductive membrane comprises a mesh structure.

21. The enclosure according to claim 3, wherein the conductive membrane comprises a mesh structure.
